(19) United States
(12) Patent Application Publication
(10) Pub. No.: US 2025/0216426 A1
(43) Pub. Date: Jul. 3, 2025

(54) DETERMINING THE ENERGY CONSUMPTION OR LOAD PROFILE OF MEDICAL APPARATUSES

(71) Applicant: Siemens Healthineers AG, Forchheim (DE)

(72) Inventors: Julian Wohlers, Erlangen (DE); Jens Gühring, Erlangen (DE); Sören Grübel, Dresden (DE); Rainer Schneider, Höchstadt (DE); Christoph Forman, Uttenreuth (DE); Christopher John Long, London (GB)

(21) Appl. No.: 19/007,542

(22) Filed: Jan. 1, 2025

(30) Foreign Application Priority Data
Jan. 2, 2024 (DE) 10 2024 200 019.1

(51) Int. Cl. G01R 22/10; G01R 19/25; G01R 21/133

(52) U.S. Cl. CPC G01R 22/10; G01R 19/2513; G01R 21/133

(57) ABSTRACT

Energy data and load profiles of a medical apparatus are to be obtained in a simple manner. For this purpose, a method is provided for determining an energy consumption or a load profile of a medical apparatus. The method is based on a load or energy consumption model. A virtual parameter of the load or energy consumption model is set. The virtual parameter corresponds to at least one real parameter of the medical apparatus. The energy consumption or the load profile of the medical apparatus is determined in dependence upon the virtual parameter.

This application claims the benefit of German Patent Application No. DE 10 2024 200 019.1, filed on Jan. 2, 2024, which is hereby incorporated by reference in its entirety.

### BACKGROUND

The present embodiments relate to a method for determining an energy consumption or load profile of a medical apparatus, and relate to a corresponding calculating apparatus and a computer program.

Medical devices or apparatuses may be different imaging or therapeutic apparatuses. For example, the present embodiments relate to medical apparatuses that have a high demand for energy or power.

Increased energy costs (e.g., in Europe) have drawn attention to the magnetic resonance tomography (MRT) or magnetic resonance imaging (MRI) devices used in radiological departments. Due to their high energy consumption, which may account for about 7.5% of the total energy consumption of a hospital, the radiology departments are responsible for a significant part of the greenhouse gas emissions caused by the facility. In radiology, MRT devices with an annual consumption of up to 100 MWh consume significantly more electricity than all other devices. This high energy consumption is primarily due to the magnetic cooling, followed by the gradient generation, both of which account for up to 75% of the total consumption. The reduction in the energy consumption of MRT units therefore depends largely on the optimization of the cooling process and the shortening of the active phases of the gradient. When optimizing a program step for energy efficiency, however, other components such as the radio-frequency power amplifier (RFPA) are also to be taken into account.

Magnetic resonance tomography units are imaging apparatuses that, in order to image an object to be examined, orient nuclear spins of the object to be examined with a strong external magnetic field and by exciting an alternating magnetic field for precession about this orientation. The precession or return of the spins from this excited state into a state with lower energy in turn generates an alternating magnetic field in response, which is received via antennas.

With the aid of magnetic gradient fields, a spatial coding is impressed on the signals, which subsequently makes it possible to allocate the received signal to a volume element. The received signal is then evaluated, and a three-dimensional imaging representation of the object to be examined is provided.

For the generation of the magnetic fields and radio-frequency signals, high powers in the range of kilowatts are to be provided, and a corresponding power is also to be dissipated by a cooling system.

In X-ray systems such as computed tomography units, high electrical powers are also required to generate the X-rays, as well as cooling the targets in the X-ray sources. The same applies to radiotherapy devices with corresponding accelerators.

Due to the complexity of the technology, it is not transparent to the user how much energy is consumed at different parameter settings. This may lead to a waste of energy in the case of a sub-optimal parameter setting.

At present, there is no solution to this problem because the energy consumption of an MRT scanner cannot be optimized, neither for a user nor for the OEMs.

Not only the energy consumption but also the load profile may be a problem. There are certainly MRT operators who, due to limited connected load, cannot fully use their device and must adjust parameters accordingly in order not to exceed certain power limits.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, more comprehensive support for the user of a medical apparatus in reducing the energy consumption or optimizing the load profile is provided.

Corresponding to the present embodiments, a method is therefore provided for determining an energy consumption or a load profile of a medical apparatus. As mentioned at the outset, the medical apparatus is, for example, an MRT system, a CT system, or an irradiation system, each of which exhibits a relatively high energy consumption or peak load. Determining the energy consumption or the load profile does not include measuring the energy consumption or the load profile. Rather, the determination is intended to include, for example, an estimation, as a result of which, for example, a virtual measuring method may be realized. Under certain circumstances, both the energy consumption and the load profile may be determined.

In a method act, a load model and/or energy consumption model for the medical apparatus is provided. The load or energy consumption model may be used to model or simulate the energy consumption or the load profile of the medical apparatus. For example, a specific energy consumption or the load profile may be inferred using certain input variables of the load or energy consumption model. The energy consumption model or load profile may be based on analytical algorithms, look-up tables, neural networks, and the like.

In a further act, a virtual parameter of the load or energy consumption model is set, where the virtual parameter corresponds to at least one real parameter of the medical apparatus. The load or energy consumption model may therefore be, for example, a digital twin of the medical apparatus that is supplemented with a virtual power and/or energy measuring device. A real parameter of the medical apparatus may be, for example, the gradient strength of an MRT system. The corresponding virtual parameter then also relates to the gradient strength in the model. Just as changing the gradient strength in the real MRT system affects the energy consumption, changing the virtual gradient strength in the load or energy consumption model also affects the estimated energy consumption or the load profile. Depending on how the virtual parameter is set, this results in a corresponding virtual or estimated energy consumption or load profile for the respective process or operation of the medical apparatus. The energy consumption or the load profile of the medical apparatus is thus determined in dependence upon the virtual parameter. In other words, the load or energy consumption model simulates the process of the medical apparatus that is set with the virtual parameter and the resulting energy consumption or the load profile. The energy consumption or the load profile may be determined as a value (e.g., total value or peak or average load for a completed process, such as the acquisition of an image sequence) or as a time profile. This profile represents the energy consumption per unit of time and thus a power. The load profile may be, for example, a power profile and/or a current profile.

It is thus possible to estimate or predict the energy consumption or the load profile of a medical apparatus without a specific measuring device. Based on such a prediction, power and/or energy optimization may be initiated.

In one example embodiment, it is provided that the virtual parameter is one of a plurality of virtual parameters of the energy consumption model, each of the virtual parameters is set, and the power and/or energy consumption of the medical apparatus is simulated in dependence upon all virtual parameters. This provides that the energy consumption model has multiple input parameters on the basis of which the energy consumption of the medical apparatus is calculated. If the medical apparatus is, for example, an MRT system, the parameters may relate, for example, to the field of view, such as gradient strength, saturation, radio-frequency energy, and the like. All these parameters ultimately influence the energy consumption and/or the load profile of the MRT system.

The plurality of virtual parameters may be determined from a header of an image data set. If, for example, the image data set has the standardized DICOM format, the recording parameters are stored in the respective header of an image. The header data items are real parameters but may be used as virtual parameters for the energy consumption model. The real parameters may thus either be used to subsequently estimate the energy consumption or the load profile for recording the respective image using the load or energy consumption model. Alternatively, the real parameters may also be used to generate predictions about the energy consumption or the load profile of new images. For example, a header parameter set may be slightly varied for a prediction in order to determine a corresponding energy consumption or the load profile.

In accordance with an alternative example embodiment, the plurality of virtual parameters are determined from a log file of the medical apparatus. This provides that when an image is acquired, the parameters are logged in a log file. The protocol data may then in turn be the starting point for a prediction of the energy consumption or the load profile for a virtual recording. Thus, values of a real image acquisition are also used here for setting the virtual parameters of the load or energy consumption model.

In a further example embodiment, it is provided that the energy consumption and/or the load profile of the medical apparatus is displayed graphically on a graphical user interface together with the virtual parameter and/or in dependence upon the virtual parameter. The graphical user interface may be, for example, a “dashboard” that may be used, for example, to graphically display functional relationships between one or more parameters and the energy consumption or the load profile. Thus, for example, the energy consumption and the load profile may be reproduced as a function or column diagram in dependence upon a specific parameter.

In another example embodiment, it is provided that the medical apparatus is configured to perform a plurality of examination steps, and the load or energy consumption model is configured to determine a respective energy consumption or a load profile for corresponding virtual examination steps. Each virtual examination step is configured with a respective virtual parameter. If, for example, an examination sequence having multiple examination steps is to be performed, the load or energy consumption model may also be capable of simulating these multiple steps in succession in relation to the energy consumption or the load profile. If necessary, a sum of the total energy consumption of all investigation steps is determined by the energy consumption model. Alternatively, a plurality of examination steps may also be performed in parallel. In this case, the energy consumption model may also be configured to determine the energy consumption of the examination steps running in parallel and, if necessary, calculate a total energy consumption. This makes it possible for the user to directly influence the individual examination steps with regard to energy consumption.

In general, the load or energy consumption model may also be used to automatically optimize the energy consumption or the load profile. For this purpose, an optimization algorithm may, for example, determine a minimum energy consumption and/or a maximum possible load profile by varying the virtual parameters accordingly.

In a further example embodiment, the medical apparatus includes an imaging facility with which a recording sequence may be acquired. Individual pieces of a corresponding virtual recording sequence are set with the plurality of virtual parameters, and a respective individual energy consumption or the load profile of each individual piece of the recording sequence and/or a total energy consumption of the recording sequence is calculated with the load or energy consumption model. It is therefore intended, for example, to obtain a recording sequence with a plurality of images. In this case, the load or energy consumption model is able to provide at least one separate virtual parameter for each recording that has an influence on the recording quality of the respective image. The load or energy consumption model may then be used to determine a corresponding energy consumption or the load profile for each individual recording of the virtual recording sequence. Thus, individual recordings, but also the entire recording sequence, may be optimized with regard to energy consumption and load profile.

According to one example embodiment, it is provided that the virtual parameter of the load or energy consumption model is set using an input interface. For example, the input interface is a human machine interface (HMI interface). A user may therefore, for example, manually set or change one or more virtual parameters of the load or energy consumption model. For this purpose, for example, buttons for number inputs and/or one or more control wheels for setting a respective virtual parameter may be provided at the input interface.

A further example embodiment may be based on the fact that the energy consumption and/or the load profile is displayed graphically and changed interactively by inputting a value of the virtual parameter via the input interface. If, for example, the energy consumption or the load profile is displayed by a bar chart, the bar height may vary in accordance with the set virtual parameter. The interactive display provides, for example, that the change of the graphic takes place with the change of the virtual parameter in real time. The user may thus immediately see how a change in the virtual parameter affects the energy consumption or the load profile.

In accordance with a further example embodiment, it is provided that planned radio-frequency pulses and gradient waveforms of a sequence protocol of an MRT apparatus are set with the virtual parameters. Radio-frequency pulses and gradient waveforms decisively influence the energy consumption and/or the load profile of an MRT system. It therefore makes sense to model and, if necessary, optimize these parameters with regard to energy consumption and/or the load profile.

In accordance with another example embodiment, the virtual parameter is reset in dependence upon the energy consumption or the load profile. If necessary, a plurality of virtual parameters are also reset in dependence upon the (respective) energy consumption and/or the load profile. This provides that a feedback loop is provided, because first the energy consumption or the load profile is calculated based on an output value of the virtual parameter, and this energy consumption and/or the load profile is then used to change the virtual parameter again. Such feedback may be used to optimize the energy consumption and/or the load profile. This optimization may be performed automatically by an algorithm. If necessary, the energy consumption and/or the load profile is also determined in dependence upon two different virtual parameters, and a compromise is found between the two parameters with regard to the energy consumption and/or the load profile. For example, gradient strength and saturation may be weighed against one another in order to optimize energy consumption.

In accordance with the present embodiments, a method is also provided for training a load model or energy consumption model for the medical apparatus by providing setting data (e.g., header, logfiles) for setting the medical apparatus, providing load or energy consumption data that is measured in dependence upon the setting data at the medical apparatus, and training a neural network with the setting data as input data and the load or energy consumption data as output data.

A neural network is thus used for the load or energy consumption model, which may learn the energy consumption and the load profile at respective settings from older headers and/or log files. In this manner, load or energy data may be obtained very reliably from the parameter settings. For example, the load or energy consumption model may be trained such that the load or energy consumption model performs one of the above-mentioned methods.

As another example, a calculating apparatus for determining an energy consumption or the load profile of a medical apparatus is provided. The calculating apparatus includes a data processing facility in which a load model or energy consumption model for the medical apparatus is implemented, and an interface for setting a virtual parameter of the load or energy consumption model. The virtual parameter corresponds to at least one real parameter of the medical apparatus. The data processing facility is configured to determine (e.g., simulate) the energy consumption or the load profile (e.g., as values, such as average, absolute value, variance, standard deviation, etc., or profile) of the medical apparatus in dependence upon the virtual parameter.

The data processing facility may be, for example, a computer or another computing unit having one or more processors and one or more storage elements. The interface may be a data interface for automatic data input or a human-machine interface for manual data input.

In addition, the calculating apparatus may be part of a control unit of the medical apparatus. In this manner, one or more set virtual parameters may be used to control the real medical apparatus.

Further, in accordance with the present embodiments, a computer program or computer program product may also be provided having commands that when executed in the above calculating apparatus causes the calculating apparatus to implement a method as illustrated above.

For applications or application situations that may arise in the method and that are not explicitly described here, it may be provided in accordance with the method that an error message and/or a request for input of a user feedback is output and/or a standard setting and/or a predetermined initial state is set.

Independent of the grammatical term usage, individuals with male, female, or other gender identities are included within the term.

### BRIEF DESCRIPTION OF THE DRAWINGS

FIG. 1 shows a schematic illustration of an example medical device in accordance with the present embodiments; and

FIG. 2 shows a schematic diagram of the execution of an example embodiment of a method in accordance with the present embodiments.

### DETAILED DESCRIPTION

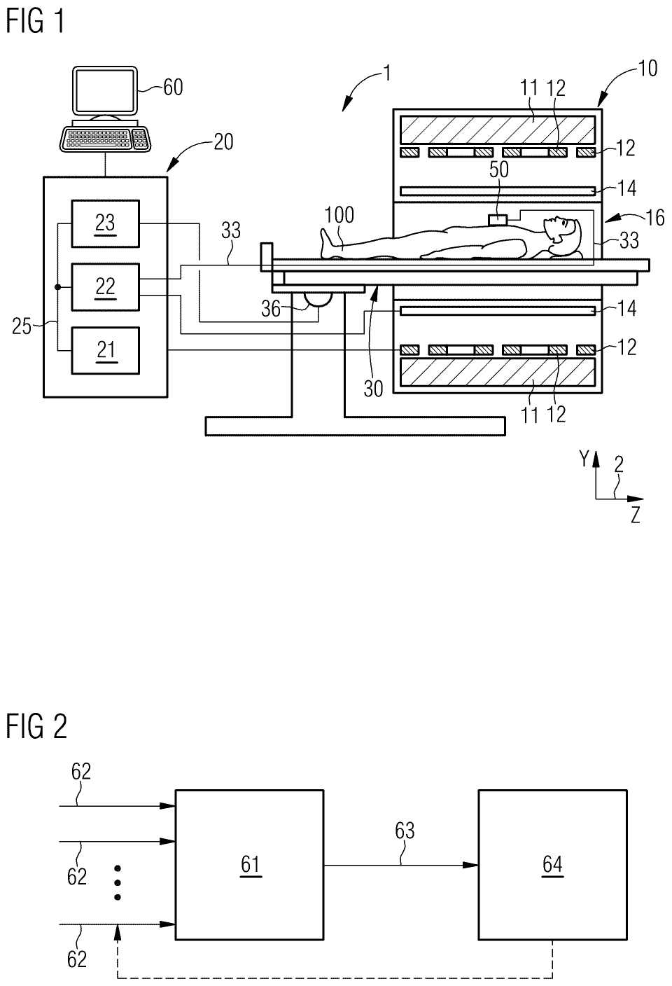

FIG. 1 illustrates a schematic illustration of an embodiment of a magnetic resonance tomography unit 1 as an example medical apparatus. In addition, other devices with a considerable need for electrical energy or power, cooling or other operating equipment, such as, for example, linear accelerators for radiotherapy, may also be provided as a medical apparatus.

The magnet unit 10 has a field magnet 11 that generates a static magnetic field BO for orienting nuclear spins of samples or of the patient 100 in a recording region. The recording region is characterized by an extremely homogeneous static magnetic field BO, where the homogeneity relates, for example, to the magnetic field strength or the magnitude. The receiving region is almost spherical and arranged in a patient tunnel 16 that extends in a longitudinal direction 2 through the magnet unit 10. A patient couch 30 may be moved in the patient tunnel 16 by the positioning unit 36. For example, the field magnet 11 is a superconducting magnet that may provide magnetic fields with a magnetic flux density of up to 3T (e.g., in the case of the latest devices even above this). However, permanent magnets or electromagnets having normally conducting coils may also be used for lower magnetic field strengths.

To maintain the low temperatures of the superconducting magnet coils, the superconducting magnet requires a cooling unit with high power consumption and equally high waste heat and thus cooling requirements.

Further, the magnet unit 10 has gradient coils 12 that are configured to temporally and spatially superimpose variable magnetic fields in three spatial directions on the magnetic field BO in order to spatially differentiate the imaging regions that are captured in the examination volume. The gradient coils 12 may be coils of normally conducting wires that may generate mutually orthogonal fields in the examination volume.

The resistive gradient coils 12 are also driven by a gradient controller 21 with very high currents and have a corresponding need for electrical energy, power, and cooling demand for the waste heat.

The magnet unit 10 further has a body coil 14 that is configured to emit a radio-frequency signal that is supplied via a signal line, into the examination volume, to receive resonance signals that are emitted by the patient 100, and to emit the resonance signals via a signal line.

A control unit 20 supplies the magnet unit 10 with the various signals for the gradient coils 12 and the body coil 14 and evaluates the received signals.

Thus, the control unit 20 has the gradient controller 21 that is configured to supply the gradient coils 12 with variable currents via supply lines that provide the desired gradient fields in the examination volume in a temporally coordinated manner.

Further, the control unit 20 has a radio-frequency unit 22 that is configured to generate a radio-frequency pulse having a predetermined temporal profile, amplitude, and spectral power distribution for exciting a magnetic resonance of the nuclear spins in the patient 100. In this case, pulse powers in the range of kilowatts may be achieved. The excitation signals may be emitted into the patient 100 via the body coil 14 or also via a local transmitting antenna.

A device controller 23 communicates via a signal bus 25 with the gradient controller 21 and the radio-frequency unit 22.

In order to receive the magnetic resonance signal, a local coil 50 in accordance with the present embodiments is arranged on the patient 100 in the patient tunnel 16 in order to detect magnetic resonance signals from an examination region in the immediate vicinity with the largest possible signal-to-noise ratio. The local coil 50 is in signal connection with a receiver in the radio-frequency unit 22 via a connecting line 33.

Further, the magnetic resonance tomography unit 1 optionally has an interface (e.g., to a data network), via which the device controller 23 may communicate with a supply controller of a supply facility, for example, send messages, and receive instructions.

In accordance with the present embodiments, a measuring device is now provided, for example, with which the energy consumption of the medical apparatus may be determined or estimated. This may be used, for example, to optimize energy consumption (e.g., by finding a compromise between the quality of the images to be recorded and the associated energy consumption). If necessary, the type of image recording may also be varied in order to optimize the energy consumption and/or the load profile. For example, weightings, relaxation times (e.g., T1 or T2), etc., may be changed as virtual parameters for the energy consumption estimate.

Thus, for example, a load model and/or energy consumption model may be created based on a statistical analysis. This load or energy consumption model may be based on look-up tables, analytical functions, machine learning, and so on. The data basis of the load or energy consumption model may be, for example, DICOM headers (standard format for medical images), log files, measured cooling temperature, parameter settings, etc.

The load or energy consumption model may be used to determine the energy consumption or the load profile of program steps with characteristic parameter settings. The corresponding energy consumption result may be presented to the user in different ways.

For example, a dashboard may be used for a retrospective display. This provides that the energy consumption and the load profile of an already performed study is calculated or estimated. In this case, input variables of the load and/or energy consumption model may be protocol files (e.g., log files) of the scanner or, for example, DICOM headers.

Alternatively, the load or energy consumption model may also be used for a predictive or prospective representation of the expected energy consumption or the load profile of a program step and/or a complete examination strategy. For example, the expected energy consumption and/or the load profile may be displayed in a user interface for the convenient creation of MRT examination sequences. For example, this consumption may be displayed for individual examination steps or as total consumption or a statistical description of the load profile. In addition, the expected energy consumption and/or the load profile may also be displayed in a parameter list of an examination sequence. Under certain circumstances, a user changes their examination strategy in order to achieve reduced energy consumption and a lower peak load.

For this purpose, the load or energy consumption model may use, for example, a sequence protocol having planned radio-frequency pulses and gradient waveforms in order to display, for example, energy contents and/or the load profile of individual examination steps.

In a further alternative, the calculated energy consumption and/or the load profile of a program step may be used for a retrospective display. Similar to the prevailing calculation of specific energy dose (SED) and specific absorption rate (SAR), the prevailing energy consumption and/or the load profile may also be calculated in an MRT scan. With such a retroactive display, a compromise may be made, for example, between information content in the image and energy consumption and/or load profile for the next examination step. The energy consumption and/or the load profile calculated using the load or energy consumption model and displayed retrospectively may also be used, for example, for corrections to the system.

As an alternative to calculating the energy consumption or the load profile based on the planned parameters, the energy consumption and, to a limited extent, the load profile may also be calculated from the cooling power of the system (e.g., cooling power-based load or energy consumption model). For this purpose, a system-specific conversion factor between cooling power and electrical power is to be determined by measurements. The cooling power may be calculated based on the temperature difference between the water inlet and outlet.

The visualization of the energy consumption or the load profile may be performed both with absolute numbers (e.g., kWh) and with relative numbers (e.g., percentage relative to a reference variable).

FIG. 2 schematically illustrates the sequence of an example embodiment of the method in order to determine or estimate the energy consumption and/or the load profile of a medical apparatus. For this purpose, a load and/or energy consumption model 61 for the medical apparatus (e.g., the magnetic resonance tomography unit 1) is provided, and one or more virtual parameters 62 of the load or energy consumption model 61 are set. The virtual parameters may correspond to real parameters for setting the real medical apparatus. Under certain circumstances, however, a virtual parameter also corresponds to a real parameter set.

This provides that a real parameter set, such as is stored in the header of an MRT image, may correspond to a single virtual parameter. In a further example embodiment, a subset of an image header (e.g., two or three parameters) may also be viewed as a single virtual parameter.

In a further act of the method in accordance with the present embodiments, the energy consumption and/or the load profile 63 of the medical apparatus is determined in dependence upon the one virtual parameter 62 or the plurality of virtual parameters 62. The energy consumption 63 is determined, for example, as an individual value or value profile over time. As a value profile, the energy consumption corresponds to a power. The load profile may be determined, for example, as a current or power profile (e.g., time profile).

The energy consumption 63 may be displayed on a user interface 64. The user interface 64 may be part of an input interface. It is possible, via the user interface 64, to change or reset one or more of the virtual parameters 62. This may be necessary as part of an optimization or a compromise.

With the virtual measuring device in accordance with the present embodiments, which is based on the load and/or energy consumption model, a conventional electricity meter on the scanner may be omitted. Corresponding investment costs for electricity meters may thus be saved. In addition, the virtual measuring device not only makes it possible to perform analyses retrospectively, but also to present an estimated energy consumption or the load profile prospectively. In this manner, the user may be given the opportunity to optimize individual program steps and ultimately the entire scanner fleet with regard to energy consumption and load profiles. The estimated power consumption and the load profile may also be used, for example, to control an infrastructure in such a manner that any load peaks are avoided.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for determining an energy consumption or load profile of a medical apparatus, the method comprising:
providing a load or energy consumption model for the medical apparatus;
setting a virtual parameter of the load or energy consumption model, wherein the virtual parameter corresponds to at least one real parameter of the medical apparatus; and
determining the energy consumption or the load profile of the medical apparatus based on the virtual parameter.

2. The method of claim 1, wherein the virtual parameter is one of a plurality of virtual parameters of the load or energy consumption model, each virtual parameter of the plurality of virtual parameters is set, and the energy consumption or the load profile of the medical apparatus is simulated in dependence upon all virtual parameters of the plurality of virtual parameters.

3. The method of claim 2, wherein the plurality of virtual parameters are determined from a header of an image data set.

4. The method of claim 2, wherein the plurality of virtual parameters are determined from a log file of the medical apparatus.

5. The method of claim 1, further comprising displaying the energy consumption or the load profile of the medical apparatus graphically on a graphical user interface together with the virtual parameter, in dependence upon the virtual parameter, or a combination thereof.

6. The method of claim 2, wherein the medical apparatus is configured to perform a plurality of examination steps, and the load or energy consumption model is configured to determine a respective energy consumption or the load profile for corresponding virtual examination steps, and wherein each of the virtual examination steps is configured with a respective virtual parameter of the plurality of virtual parameters.

7. The method of claim 6, wherein the medical apparatus includes an imaging facility with which a recording sequence is acquirable, individual pieces of a corresponding virtual recording sequence are set with the plurality of virtual parameters, and a respective individual energy consumption of each individual piece of the recording sequence, a total energy consumption of the recording sequence is calculated with the load or energy consumption model, or a combination thereof.

8. The method of claim 1, wherein the virtual parameter of the load or energy consumption model is set with the aid of an input interface.

9. The method of claim 8, further comprising:
displaying the energy consumption, the load profile, or the energy consumption and the load profile graphically; and
interactively changing the energy consumption, the load profile, or the energy consumption and the load profile, the interactively changing comprising inputting a value of the virtual parameter via the input interface.

10. The method of claim 2, wherein planned radio-frequency pulses and gradient waveforms of a sequence protocol of a magnetic resonance tomography (MRT) apparatus are set with the plurality of virtual parameters.

11. The method of claim 1, wherein the virtual parameter is reset in dependence upon the energy consumption, the load profile, or the energy consumption and the load profile.

12. A method for training a load or energy consumption model for a medical apparatus, the method comprising:
providing setting data for setting the medical apparatus;
providing energy consumption data or load profiles that are measured in dependence upon the setting data at the medical apparatus;
training a neural network with the setting data and the energy consumption data or load profiles.

13. The method of claim 12, further comprising:
determining an energy consumption or load profile of a medical apparatus, the determining comprising:
providing the load or energy consumption model for the medical apparatus;
setting a virtual parameter of the load or energy consumption model, wherein the virtual parameter corresponds to at least one real parameter of the medical apparatus; and
determining the energy consumption or the load profile of the medical apparatus based on the virtual parameter.

14. A calculating apparatus for determining an energy consumption or a load profile of a medical apparatus, the calculating apparatus comprising:
a data processing facility in which a load model or energy consumption model for the medical apparatus is implemented; and
an interface for setting a virtual parameter of the load or energy consumption model, wherein the virtual parameter corresponds to at least one real parameter of the medical apparatus,
wherein the data processing facility is configured to determine the energy consumption or the load profile of the medical apparatus in dependence upon the virtual parameter.

15. In a non-transitory computer-readable storage medium that stores instructions executable by one or more processors to determine an energy consumption or load profile of a medical apparatus, the instructions comprising:
providing a load or energy consumption model for the medical apparatus;
setting a virtual parameter of the load or energy consumption model, wherein the virtual parameter corresponds to at least one real parameter of the medical apparatus; and
determining the energy consumption or the load profile of the medical apparatus based on the virtual parameter.
